(19) United States
(12) Patent Application Publication
(10) Pub. No.: US 2025/0333294 A1
(43) Pub. Date: Oct. 30, 2025

(54) DEVICE INCLUDING MEMS SENSOR AND METHOD OF MANUFACTURING THE SAME

(71) Applicant: Infineon Technologies AG, Neubiberg (DE)

(72) Inventors: Klaus ELIAN, Alteglofsheim (DE); Horst THEUSS, Wenzenbach (DE); Anna GRUBER, Wiesent (DE); Michael WEBER, Mainburg (DE); Rainer Markus SCHALLER, Aichen (DE); Thea GÖTZ, Regensburg (DE)

(21) Appl. No.: 19/184,910

(22) Filed: Apr. 21, 2025

(30) Foreign Application Priority Data
Apr. 29, 2024 (DE) 102024203979.9

(51) Int. Cl. B81B 7/00; B81C 1/00

(52) U.S. Cl. CPC B81B 7/0058; B81C 1/00793; B81B 2201/0264; B81B 2203/0127; B81B 2207/07; B81C 2201/0176; B81C 2201/0181; B81C 2203/0136

(57) ABSTRACT

According to some implementations, a device is provided, including: a base element, a MEMS sensor provided on the base element, and at least one bond wire electrically coupling the MEMS sensor to the base element. The device further includes a protective coating covering the MEMS sensor, the at least one bond wire and at least part of the base element, and a gel provided on the protective coating.

### CROSS-REFERENCE TO RELATED APPLICATION

This application claims priority to Germany Patent Application No. 102024203979.9 filed on Apr. 29, 2024, the content of which is incorporated by reference herein in its entirety.

### TECHNICAL FIELD

The present application relates to devices including a micro-electrical mechanical system (MEMS) sensor and to methods of manufacturing such devices.

### BACKGROUND

Micro-electromechanical system (MEMS) sensors may be formed in materials like semiconductor materials, for example silicon by selectively structuring and removing material. One example of such MEMS sensors are pressure sensors, where a membrane may be formed sealing a cavity. A change of ambient pressure may deform the membrane, which may be detected using for example strain sensors or by capacitive measurements of a capacity between the membrane serving as a first electrode and a second, stationary electrode. A further example for MEMS sensors are acceleration sensors, where an inertial mass is coupled to a membrane of a pressure sensor. Further examples include gas sensors and ultrasonic sensors.

In some conventional approaches, such MEMS sensors are covered by a PFAS (per- and polyfluoroalkyl substances) gel to provide protection against particles and chemical influences which could for example lead to a corrosion.

However, in recent years concerns have been expressed regarding the impact of PFAS on the environment, and in some jurisdictions, legislation is under way or already enacted restricting the use of such substances.

### SUMMARY

According to an implementation, a device is provided, including: a base element, a MEMS sensor provided on the base element, at least one bond wire electrically coupling the MEMS sensor to the base element, a protective coating covering the MEMS sensor, the at least one bond wire and at least part of the base element, and a gel provided on the protective coating.

According to another implementation, a method is provided, including: providing a base element, providing a MEMS sensor on the base element, electrically coupling the MEMS sensor to the base element using at least one bond wire, coating the MEMS sensor, the at least one bond wire and at least part of the base element with a protective coating, and providing a gel on the protective coating.

The above summary is merely a brief overview over some implementations and is not to be construed as limiting.

### BRIEF DESCRIPTION OF THE DRAWINGS

FIG. 1 is a flowchart illustrating a method according to an implementation.

FIGS. 2A-2C are schematic cross-sectional views of a device according to an implementation in different stages of the manufacturing method of FIG. 1.

### DETAILED DESCRIPTION

In the following various implementations will be described in detail referring to the attached drawings. These implementations serve as examples only and are not to be construed as limiting, as other implementations may include different features than the ones described above.

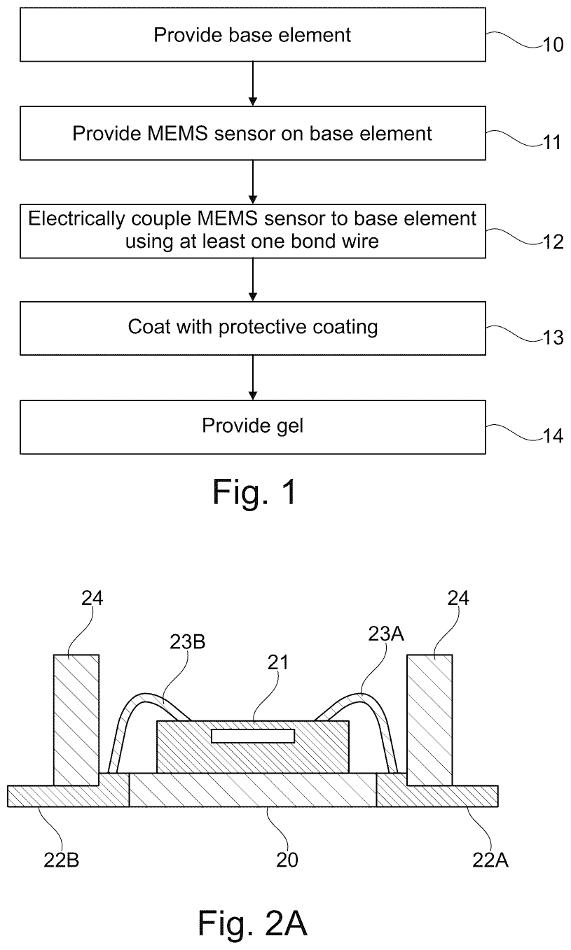

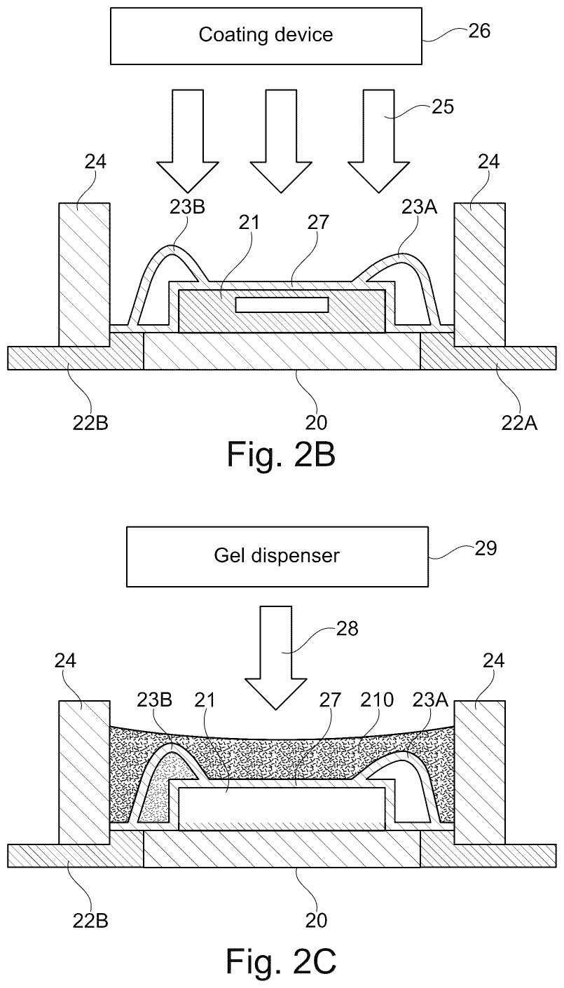

FIG. 1 is a flowchart of a method for manufacturing a device according to an implementation, and FIGS. 2A-2C show a device in different stages of manufacture. FIGS. 2A-2C will be described jointly together with the method of FIG. 1 for better illustration. However, the method of FIG. 1 may also be used to manufacture devices other than the ones shown in FIGS. 2A-2C, and the devices of FIGS. 2A-2C may also be manufactured by other methods than the one of FIGS. 2A-2C.

In FIGS. 2A-2C, the same reference numerals designate corresponding elements, which elements will therefore not be described repeatedly.

At 10, the method comprises providing a base element. As an example, in FIG. 2A a base element 20 is shown. The base element may for example comprise a printed circuit board, a lead frame, a premolded plastic element or a ceramic element, but is not limited thereto. The base element in some implementations includes electrically conducting circuit paths and contact areas for conducting electric signals, voltages, currents, etc. As an example, in FIG. 2A two circuit paths 22A, 22B are illustrated.

At 11, the method comprises providing a MEMS sensor on the base element. In the example of FIG. 2A, a pressure sensor 21 having a cavity sealed by a membrane is provided on base element 20. MEMS sensor 21 may be attached to base element 20 in any conventional manner, for example using a glue, using soldering or the like. In some implementations (not shown in FIG. 2A), base element 20 may include electrical contact elements in an area where MEMS sensor 21 is mounted, and MEMS sensor 21 may include corresponding contact elements, for establishing electrical contact through the mounting.

At 12, the method of FIG. 1 comprises electrically coupling the MEMS sensor to the base element using at least one bond wire. As an example, in FIG. 2A, two bond wires 23A, 23B are shown coupling MEMS sensor 21 to conductive paths 22A, 22B, respectively.

For example, bond wires 23A, 23B may couple a membrane of MEMS sensor 21 and a counter electrode to the membrane electrically to the base plate, such that for example capacitance measurements may be performed. In other implementations, for example a strain sensor on a membrane or any other electrical parts of MEMS sensors 21 may be electrically contacted. In other implementations, more or less bond wires than the two bond wires shown in FIG. 2A may be provided.

Additionally, as shown in FIG. 2A, a side wall element 24 may be provided surrounding MEMS sensor 21. Side wall element 24 may for example be a ring-shaped element made of a non-conducting material or a conducting material like a metal coated with a non-conducting material and may be fixed to base element 20 in any conventional manner. In other implementations, side wall element 24 may be formed integral with base element 20, for example if base element 20 is based on a molded plastic element. As will be explained later, side wall element 24 together with base plate 20 forms a space for filling a gel into the space. However, in other implementations side wall element 24 may be omitted.

At 13, the method comprises coating the MEMS sensor, the at least one bond wire and at least part of the base element with a protective coating. This is illustrated in FIG. 2B, where a coating device 26 provides a coating 27 as indicated by arrows 25. In the example of FIG. 2B, coating 27 coats MEMS sensor 21, bond wires 23A, 23B and parts of base element 20 on an inside of side wall element 24. Coating 27 includes a material which protects the coated elements, in particular metallic parts thereof, from corrosion, e.g., by protecting them from corrosive or corrosion-supporting substances like chemicals. For example, coating 27 may provide protection against salt solutions, precipitates of acids or bases, or iodine compositions (which may for examples be contaminations from tubes). As an example, the coating may comprise a silicon oxide or a metal oxide, but is not limited thereto.

A thickness of the coating may be selected such that the functionality of the MEMS sensor like MEMS sensor 21 is not significantly affected. To this end, the thickness of the coating may be below (e.g., less than) 100 nm or below 50 nm, for example about 30 nm. Several possibilities for the coating at 13 in FIG. 1 and correspondingly for the implementation of coating device 26 in FIG. 2B may be used.

One possibility is a plasma deposition using for example Hexamethyl Disilizane (HMDS) or Hexamethyl Disiloxane (HMDSO) as precursors. Conventional deposition techniques using for example a plasma nozzle may thus be used to deposit silicon oxide layer with a thickness of a about 30 nm using such precursors. Another possibility for coating is atomic layer deposition (ALD), where a surface to be coated is covered for example with a first reacting agent, then first reacting agent not appearing to the surface to be coated is removed, and then a second reacting agent reacting with the first reacting agent to the desired coating material is provided. In this way, for example metal oxides like aluminum oxide, may be used as a coating material, and the thickness may be adjusted with high precision. The metal oxide may also be hydrolysed, for example aluminum oxide (Al₂O₃) may be hydrolysed to Al(OH)₃.

Returning to FIG. 1, at 14 the method then comprises providing a gel on the reflective coating. This is illustrated in FIG. 2C, where as indicated by an arrow 28 a gel 210 is filled in the space defined by side wall element 24 and base plate 20 such that it covers the coating and therefore the bond wires 23A, 23B, MEMS sensor 21 and parts of base element 20 as shown. Gel dispenser 29 may for example include a nozzle or similar element to fill the gel into the space enclosed by side wall element 24. In case no side wall element 24 is used, for example the gel may cover the coating in a dome-like shape.

The gel used, like gel 210, may be a fluorine-free gel, for example a silicone gel. Such a silicon gel provides a similar mechanical protection as conventionally used PFAS gels, for example protection against particles settling on sensor 21. Further, a silicon-based gel or other fluorine-free gel may provide less protection against corrosion than conventional PFAS gels. However, as a coating like coating 27 is provided which protects in particular metallic parts, in some implementations the overall protection of the combination of coating and fluorine-free gel may be similar or even better compared to the protection conferred by conventional PFAS gels, without the need to use such substances.

### Aspects

Some implementations are defined by the following aspects:

Aspect 1. A device, comprising:
a base element,
a MEMS sensor provided on the base element,
at least one bond wire electrically coupling the MEMS sensor to the base element,
a protective coating covering the MEMS sensor, the at least one bond wire and at least part of the base element, and
a gel provided on the protective coating.

Aspect 2. The device of aspect 1, wherein the base element comprises at least one of a printed circuit board, a leadframe, a plastic element or a ceramic element.

Aspect 3. The device of aspect 1 or 2, further comprising a sidewall element provided on the base element surrounding the MEMS sensor, wherein the gel is filled in a space defined by the sidewall element and the base element.

Aspect 4. The device of any one of aspects 1 to 3, wherein a thickness of the protective coating is below 100 nm.

Aspect 5. The device of aspect 4, wherein the thickness is below 50 nm.

Aspect 6. The device of any one of aspects 1 to 5, wherein the coating is configured to protect the MEMS sensor, the at least one bond wire and the at least part of the base element against corrosive substances.

Aspect 7. The device of any one of aspects 1 to 6, wherein the coating comprises at least one of a silicon oxide or a metal oxide.

Aspect 8. The device of any one of aspects 1 to 7, wherein the gel is a fluorine free gel.

Aspect 9. The device of any one of aspects 1 to 8, wherein the gel comprises a silicone gel.

Aspect 10. The device of any one of aspects 1 to 9, wherein the at least part of the base element comprises a contact area or a circuit path.

Aspect 11. The device of any one of aspects 1 to 10, wherein the MEMS sensor comprises a pressure sensor.

Aspect 12. A method, comprising:
providing a base element,
providing a MEMS sensor on the base element,
electrically coupling the MEMS sensor to the base element using at least one bond wire,
coating the MEMS sensor, the at least one bond wire and at least part of the base element with a protective coating, and
providing a gel on the protective coating.

Aspect 13. The method of aspect 12, wherein coating comprises at least one of a plasma coating or an atomic layer deposition.

Aspect 14. The method of aspect 12 or 13, wherein the base element comprises at least one of a printed circuit board, a leadframe, a plastic element or a ceramic element.

Aspect 15. The method of any one of aspects 12 to 14, further comprising providing a sidewall element on the base element surrounding the MEMS sensor, wherein providing the gel comprises filling the gel into a space defined by the sidewall element and the base element.

Aspect 16. The method of any one of aspects 12 to 15, wherein a thickness of the protective coating is below 100 nm.

Aspect 17. The method of aspect 16, wherein the thickness is below 50 nm.

Aspect 18. The method of any one of aspects 12 to 17, wherein the coating is configured to protect the MEMS sensor, the at least one bond wire and the at least part of the base element against corrosive substances.

Aspect 19. The method of any one of aspects 12 to 18, wherein the coating comprises at least one of a silicon oxide or a metal oxide.

Aspect 20. The method of any one of aspects 12 to 19, wherein the gel is a fluorine free gel.

Aspect 21. The method of any one of aspects 12 to 20, wherein the gel comprises a silicone gel.

Aspect 22. The method of any one of aspects 12 to 21, wherein the at least part of the base element comprises a contact area or a circuit path.

Aspect 23. The method of any one of aspects 12 to 22, wherein the MEMS sensor (21) comprises a pressure sensor.

Although specific implementations have been illustrated and described herein, it will be appreciated by those of ordinary skill in the art that a variety of alternate and/or equivalent implementations may be substituted for the specific implementations shown and described without departing from the scope of the present implementation. This application is intended to cover any adaptations or variations of the specific implementations discussed herein. Therefore, it is intended that this implementation be limited only by the claims and the equivalents thereof.

1. A device, comprising:
a base element;
a micro-electrical mechanical system (MEMS) sensor provided on the base element;
at least one bond wire electrically coupling the MEMS sensor to the base element;
a protective coating covering the MEMS sensor, the at least one bond wire and at least part of the base element; and
a gel provided on the protective coating.

2. The device of claim 1, wherein the base element comprises at least one of a printed circuit board, a leadframe, a plastic element, or a ceramic element.

3. The device of claim 1, further comprising:
a sidewall element provided on the base element surrounding the MEMS sensor, wherein the gel is filled in a space defined by the sidewall element and the base element.

4. The device of claim 1, wherein a thickness of the protective coating is below 100 nm.

5. The device of claim 1, wherein the protective coating is configured to protect the MEMS sensor, the at least one bond wire and the at least part of the base element against corrosive substances.

6. The device of claim 1, wherein the protective coating comprises at least one of a silicon oxide or a metal oxide.

7. The device of claim 1, wherein the gel is a fluorine free gel.

8. The device of claim 1, wherein the gel comprises a silicone gel.

9. The device of claim 1, wherein the at least part of the base element comprises a contact area or a circuit path.

10. The device of claim 1, wherein the MEMS sensor comprises a pressure sensor.

11. A method, comprising:
providing a base element,
providing a micro-electrical mechanical system (MEMS) sensor on the base element,
electrically coupling the MEMS sensor to the base element using at least one bond wire,
coating the MEMS sensor, the at least one bond wire and at least part of the base element with a protective coating, and
providing a gel on the protective coating.

12. The method of claim 11, wherein the protective coating comprises at least one of a plasma coating or an atomic layer deposition.

13. The method of claim 11, further comprising:
providing a sidewall element on the base element surrounding the MEMS sensor, wherein providing the gel comprises filling the gel into a space defined by the sidewall element and the base element.

14. The method of claim 11, wherein a thickness of the protective coating is below 100 nm.

15. The method of claim 11, wherein the protective coating is configured to protect the MEMS sensor, the at least one bond wire and the at least part of the base element against corrosive substances.

16. The method of claim 11, wherein the protective coating comprises at least one of a silicon oxide or a metal oxide.

17. The method of claim 11, wherein the gel is a fluorine free gel.

18. The method of claim 11, wherein the gel comprises a silicone gel.

19. The method of claim 11, wherein the at least part of the base element comprises a contact area or a circuit path.

20. The method of claim 11, wherein the MEMS sensor comprises a pressure sensor.
